(19) United States
(12) Patent Application Publication
(10) Pub. No.: US 2025/0218870 A1
(43) Pub. Date: Jul. 3, 2025

(54) SELF-ALIGNING BACKSIDE GATE CONNECTION

(71) Applicant: Applied Materials, Inc., Santa Clara, CA (US)

(72) Inventors: Ashish PAL, San Ramon, CA (US); Gregory COSTRINI, Flanders, NJ (US); El Mehdi BAZIZI, San Anselmo, CA (US); Veeraraghavan S. BASKER, Schenectady, NY (US); Benjamin COLOMBEAU, Salem, MA (US); Balasubramanian PRANATHARTHIHARAN, Santa Clara, CA (US)

(21) Appl. No.: 19/008,286

(22) Filed: Jan. 2, 2025

Related U.S. Application Data
(60) Provisional application No. 63/617,271, filed on Jan. 3, 2024.

(51) Int. Cl. H01L 21/768; H01L 21/78; H10D 30/00

(52) U.S. Cl. CPC H01L 21/76897; H01L 21/7806; H10D 30/501

(57) ABSTRACT

Embodiments of the present disclosure relate to a method of forming a contact structure on a substrate. The method includes forming a high aspect ratio (HAR) feature within a substrate having a device formed thereon. The device includes a plurality of channels disposed through a polysilicon layer and extending in a first direction, and an isolation layer disposed on the substrate, the polysilicon layer separated from the isolation layer by a dielectric layer. The forming of the HAR feature is formed a first distance in a second direction from the plurality of channels and includes removing a portion of the isolation layer and the polysilicon layer. The method further includes etching the polysilicon layer to expose a top surface of the isolation layer that is opposite to a surface that is disposed on the surface of the substrate, and exposing a metal layer within the HAR feature.

### CROSS-REFERENCE TO RELATED APPLICATIONS

This application is a continuation application of U.S. Patent Application Ser. No. 63/617,271, filed Jan. 3, 2024, which is incorporated herein by reference.

### BACKGROUND

### Field

Embodiments of the present disclosure generally relate to a semiconductor device fabrication, and more particularly, to systems and methods of forming gate contact structures.

### Description of the Related Art

Integrated circuits have evolved into complex devices that can include billions of transistors, capacitors, and resistors on a single chip. In the course of integrated circuit evolution, functional density (that is, the number of interconnected devices per chip area) has generally increased while geometry size (that is, the smallest component (or line) that can be created using a fabrication process) has decreased.

Microelectronic devices are fabricated on a semiconductor substrate as integrated circuits in which various conductive layers are interconnected with one another to permit electronic signals to propagate within the device. An example of such devices may include high-performance computing, mobile devices, internet of things (IoT) devices, memory (for example, DRAM (dynamic random access memory)) and logic devices, including both planar and three-dimensional structures. Three-dimensional structures include finFET (fin field-effect transistor), MOSFET (metal-oxide-semiconductor field-effect transistor), GAA FET (gate-all-around field-effect transistor), CFET (complimentary field-effect transistor) and similar.

As the functional density increases, geometry size has not always decreased at the same rate. This leaves more devices with increasing power delivery connections, device connections, and device interconnections competing for the same limited front side space. This is especially true with dealing with three-dimensional structures. Accordingly, there is a need in the art for solutions to mitigate front side wiring congestion.

### SUMMARY

Embodiments of the present disclosure generally relate to a semiconductor device fabrication, and more particularly, to methods of forming gate contact structures.

In one embodiment, the method includes forming a high aspect ratio (HAR) feature within a substrate having a device formed thereon. The device includes a plurality of channels disposed through a polysilicon layer and extending in a first direction, and an isolation layer disposed on the substrate, the polysilicon layer separated from the isolation layer by a dielectric layer. The forming of the HAR feature is formed a first distance in a second direction from the plurality of channels and includes removing a portion of the isolation layer and the polysilicon layer. The method further includes etching the polysilicon layer to expose a top surface of the isolation layer that is opposite to a surface that is disposed on the surface of the substrate, and exposing a metal layer within the HAR feature.

In another embodiment, a method of forming a contact structure in a substrate is provided. The method includes, forming a high aspect ratio (HAR) feature within a substrate. The substrate includes a device formed in the substrate. The device includes an isolation layer formed on the substrate and a plurality of channels surrounded by a polysilicon layer. The plurality of channels are separated from the polysilicon layer by an oxide layer. The polysilicon layer is disposed over the isolation layer. The method further includes removing the polysilicon layer to expose the oxide layer, patterning the exposed oxide layer and isolation layer to form a high aspect ratio (HAR) feature through the isolation layer, depositing a metal layer within the HAR feature, and removing the substrate to expose a contact region that includes a portion of the metal layer. The HAR feature extends to a first surface of the substrate.

In another embodiment, a method of forming a contact structure in a substrate is provided. The method includes, transferring a device into a processing chamber. The device includes a substrate having silicon, an isolation layer formed on the substrate, and a gate metal layer disposed above the a isolation layer. The method further includes etching the device to form a high aspect ratio (HAR) feature through the gate metal fill, the isolation layer, and the substrate, depositing a dielectric filler material within the HAR feature, removing the substrate to expose a lower surface of the isolation layer, removing the dielectric filler material, and disposing a gate metal fill within the HAR feature.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a schematic top view of a multi-chamber processing system, according to embodiments described herein.

FIGS. 2A-2C depict process flow diagrams of methods of forming a semiconductor structure according to embodiments described herein.

FIG. 3 is a schematic isometric view of an example GAA FET semiconductor structure according to embodiments described herein.

FIGS. 4A-4G illustrate cross-sectional views of portions of a semiconductor device substrate during a method according to embodiments described herein.

FIG. 5 illustrates a cross-sectional views of a portion of a semiconductor device substrate during a method according to embodiments described herein.

FIGS. 6A-6H illustrate cross-sectional views of portions of a semiconductor device substrate during a method according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the following disclosure, reference may be made to one or more embodiments. However, one of skill in the art does appreciate that the disclosure is not limited to specifically to the described embodiments. Rather, any combination of features and elements, whether related to different embodiments or not, is envisioned to implement and practice one or more embodiments provided by the disclosure. Furthermore, although the one or more embodiments presented in the disclosure may achieve advantages over other possible solutions, the prior art (if existing), and combinations thereof, whether or not a particular advantage is achieved by a given embodiment is not limited by this disclosure. The aspects, features, embodiments, and advantages provided are merely illustrative. These are not considered elements or limitations of the appended claims except where explicitly recited in one or more of the Claims. Likewise, one of skill in the art should not construe a reference to “the disclosure” as a generalization of any disclosed subject matter.

Microelectronic devices are fabricated on a semiconductor substrate as integrated circuits in which various conductive layers are interconnected with one another to permit electronic signals to propagate within the device. An example of such devices may include high-performance computing, mobile devices, internet of things (IoT) devices, memory (for example, DRAM (dynamic random access memory)) and logic devices, including both planar and three-dimensional structures. Three-dimensional structures include finFET (fin field-effect transistor), MOSFET (metal-oxide-semiconductor field-effect transistor), GAA FET (gate-all-around field-effect transistor), CFET (complimentary field-effect transistor) and similar.

As the functional density increases, geometry size has not always decreased at the same rate. This leaves more devices with increasing power delivery connections, device connections, and device interconnections competing for the same limited front side space. This is especially true with dealing with three-dimensional structures.

By providing methods for self-aligned backside gate connections, the congestion of current techniques can be mitigated allowing for a continuation of area scaling. While not limited to a particular type of device, with respect to quasi-planar devices, such as GAA or FinFET, methods disclosed within allow local wiring of the gate from the backside of the device substrate reducing front side wiring congestion and parasitic gate capacitance by moving the front side gate local wiring to the less congested back side. With respect to CFET devices, front side wiring congestion and parasitic gate capacitance reductions may be reduced. Further, current methods of contacting the lower device gate of CFET devices require complicated techniques and processes to connect front side wiring to the lower gate contact. Methods disclosed within allow for a reduction in process complexity by providing local wiring to the lower device gate of CFET devices from the backside of the substrate.

In addition, for CFET devices, the gate contact technology requires significant innovation to enable contacting the bottom device gate from the front side wiring. This invention would significantly reduce the process complexity to provide local wiring to the bottom device gate.

### Processing System Example

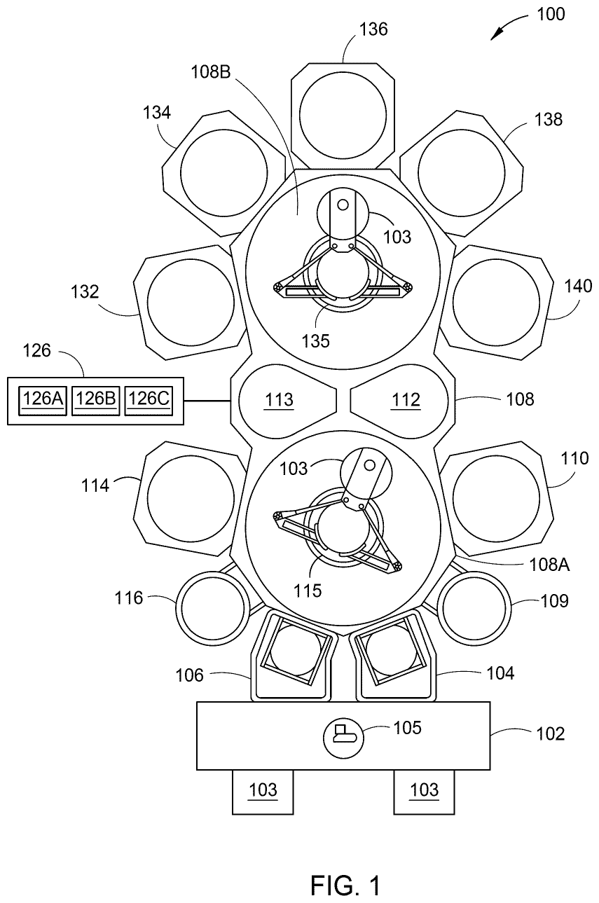

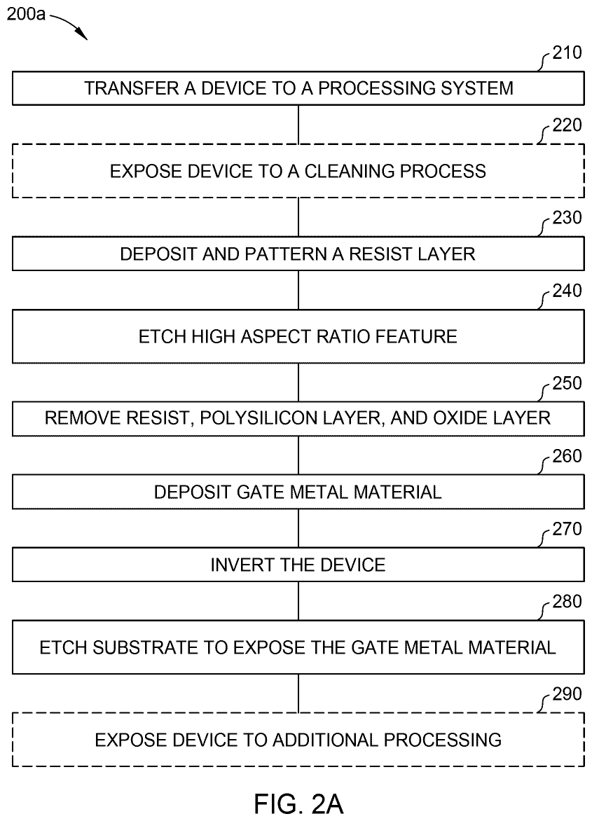

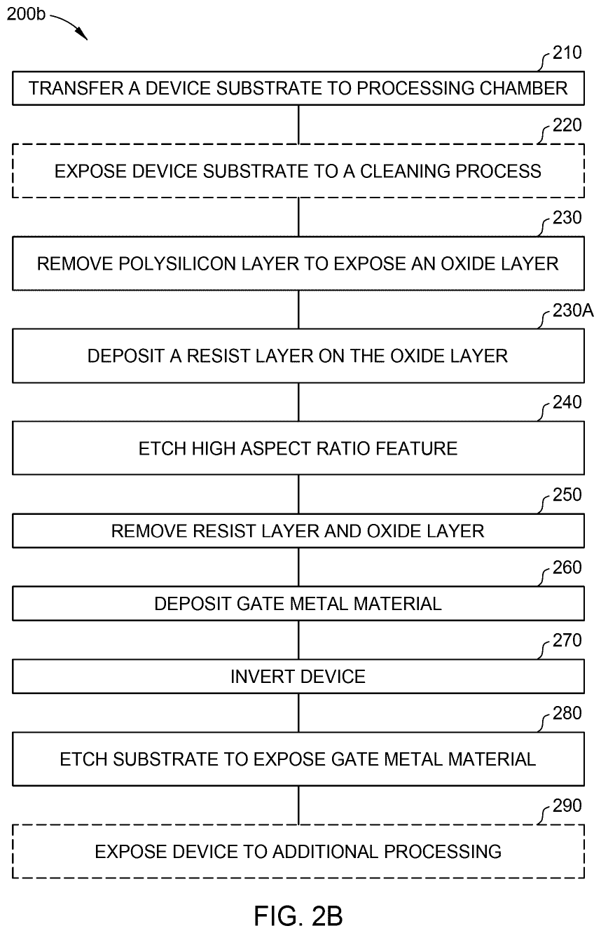

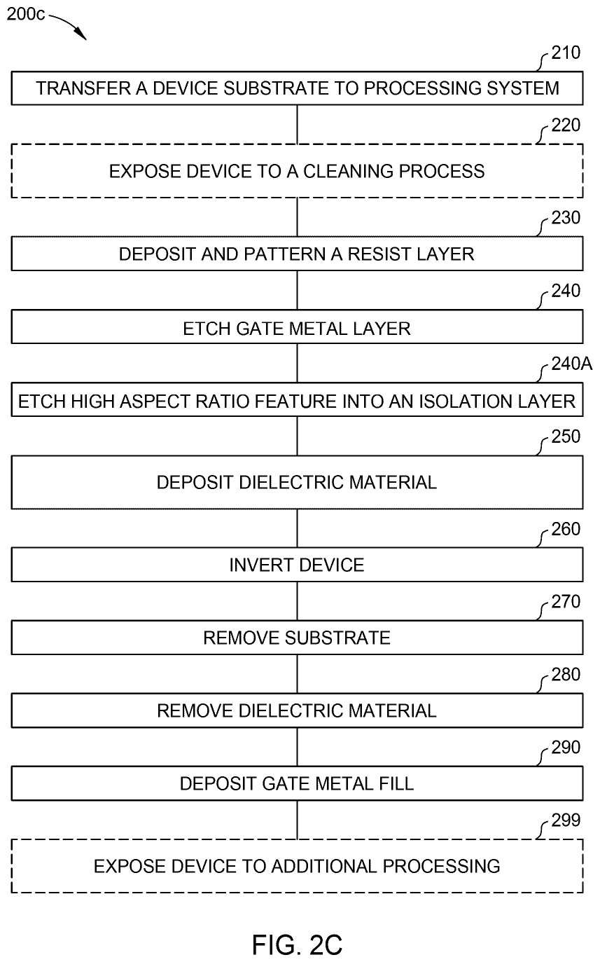

FIG. 1 illustrates a schematic representation of a processing system 100 for use with one or more embodiments of the disclosure. In one or more embodiments, the processing system 100 may be utilized to perform all or a portion of method 200a, method 200b, or method 200c of FIGS. 2A-2C.

As detailed below, substrates in the processing system 100 may be processed in and transferred between the various chambers without exposing the substrates to an ambient environment exterior to the processing system 100 (for example, an atmospheric ambient environment such as may be present in a fab). For example, the substrates may be processed in and transferred between the various chambers maintained at a low pressure (for example, less than or equal to about 300 Torr), or sub-atmospheric pressure, such as a vacuum environment, without breaking the reduced relative pressure or vacuum environment among various processes performed on the substrates in the processing system 100. Accordingly, the processing system 100 may provide for an integrated solution for some processing of substrates.

FIG. 1 is a schematic top view of the processing system 100 (also referred to as a “processing platform”), according to embodiments described herein. The processing system 100 generally includes an equipment front-end module (EFEM) 102 for loading substrates into the processing system 100, a first load lock chamber 104 coupled to the EFEM 102, a transfer chamber 108 coupled to the first load lock chamber 104, and a plurality of other chambers coupled to the transfer chamber 108 as described in detail below. The EFEM 102 generally includes one or more robots 105 that are configured to transfer substrates from the front opening unified pods (FOUPs) 103 to at least one of the first load lock chamber 104 or the second load lock chamber 106. Proceeding counterclockwise around the transfer chamber 108 from the buffer portion 108A of the first load lock chamber 104, the processing system 100 includes a first dedicated degas chamber 109, a first pre-clean chamber 110, a first pass-through chamber 112, a second pass-through chamber 113, a second pre-clean chamber 114, a second degas chamber 116 and the second load lock chamber 106. The buffer portion 108A of the transfer chamber 108 includes a first robot 115 that is configured to transfer substrates to each of the load lock chambers 104, and 106, the degas chambers 109, and 116, the pre-clean chambers 110, and 114 and the pass-through chambers 112, and 113.

The back-end portion 108B of the transfer chamber 108 includes a second robot 135 that is configured to transfer substrates to each of the pass-through chambers 112, 113 and the processing chambers coupled to the back-end portion 108B of the processing system 100. The processing chambers can include a first processing chamber 132, a second processing chamber 134, a third processing chamber 136, a fourth processing chamber 138 and a fifth process chamber 140. In general, the processing chambers 132, 134, 136, 138, 140 can include at least one of an atomic layer deposition (ALD) chamber, chemical vapor deposition (CVD) chamber, physical vapor deposition (PVD) chamber, etch chamber, degas chamber, an anneal chamber, and other type of semiconductor substrate processing chamber. In some embodiments, one or more of the processing chambers 132, 134, 136, 138, 140 are a PVD chamber. In some examples, the processing chamber 110 may be capable of performing an etch process, the processing chamber 114 may be capable of performing a cleaning process or an annealing process, and the processing chambers 132, 134, 136, 138, 140 may be capable of performing respective CVD or ALD deposition processes.

The buffer portion 108A and back-end portion 108B of the transfer chamber 108 and each chamber coupled to the transfer chamber 108 may be maintained at a vacuum state. As used herein, the term “vacuum” may refer to pressures less than 760 Torr, and will typically be maintained at pressures near 10⁻⁵ Torr (that is, ˜10⁻³ Pa). However, some high-vacuum systems may operate below near 10⁻⁷ Torr (that is, ˜10⁻⁵ Pa). In certain embodiments, the vacuum is created using a rough pump and/or a turbomolecular pump coupled to the transfer chamber 108 and to each of the one or more process chambers (for example, process chambers 109-140). However, other types of vacuum pumps are also contemplated.

A system controller 126, such as a programmable computer, is coupled to the processing system 100 for controlling one or more of the components therein. For example, the system controller 126 may control the operation of one or more of the processing chambers, such as processing chambers 132, 134, 136, 138, 140. In operation, the system controller 126 enables data acquisition and feedback from the respective components to coordinate processing in the processing system 100.

The system controller 126 includes a programmable central processing unit (CPU) 126A, which is operable with a memory 126B (for example, non-volatile memory) and support circuits 126C. The support circuits 126C (for example, cache, clock circuits, input/output subsystems, power supplies, etc., and combinations thereof) are conventionally coupled to the CPU 126A and coupled to the various components within the processing system 100.

In some embodiments, the CPU 126A is one of any form of general purpose computer processor used in an industrial setting, such as a programmable logic controller (PLC), for controlling various monitoring system component and sub-processors. The memory 126B, coupled to the CPU 126A, is non-transitory and is typically one or more of readily available memory such as random access memory (RAM), read only memory (ROM), floppy disk drive, hard disk, or any other form of digital storage, local or remote.

Herein, the memory 126B is in the form of a computer-readable storage media containing instructions (for example, non-volatile memory), that when executed by the CPU 126A, facilitates the operation of the processing system 100. The instructions in the memory 126B are in the form of a program product such as a program that implements the methods of the present disclosure (for example, middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (for example, read-only memory devices within a computer such as CD-ROM disks readable by a CD-ROM drive, flash memory, ROM chips or any type of solid-state non-volatile semiconductor memory) on which information is permanently stored; and (ii) writable storage media (for example, floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. The various methods disclosed herein may generally be implemented under the control of the CPU 126A by the CPU 126A executing computer instruction code stored in the memory 126B (or in memory of a particular processing chamber) as, for example, a software routine. When the CPU 126A executes the computer instruction code, the CPU 126A controls the chambers to perform processes in accordance with the various methods described herein.

### Example Gate-All-Around Field Effect Transistor Structure

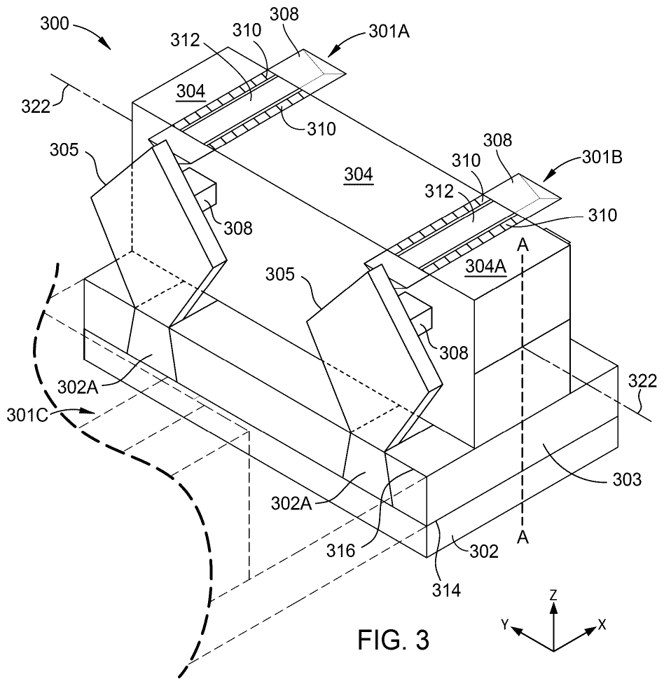

FIG. 3 is an exemplary semiconductor structure 300 for a Gate-All-Around Field Effect Transistor (GAA FET). The semiconductor structure 300 includes a substrate 302, an isolation layer 303 formed on the substrate 302, a first GAA FET module 301A and a second GAA FET module 301B. The GAA FET module 301A and the GAA FET module 301B include a gate region 304. In an early stage of a replacement gate type of GAA formation process the gate region 304 can include a material such as polysilicon (e.g., polysilicon layer 406), and after the GAA formation process is complete the gate region 304 will contain one or more gate metals. GAA FET module 301C is shown as a dashed section that partially depicts a region which would share a portion of the substrate 302 with GAA FET module 301A and GAA FET module 301B. GAA FET module 301A and GAA FET module 301B are viewed through a partial sectioned opening between GAA FET module 301C and the GAA FET modules 301A and 301B.

The substrate 302 may be a silicon based material or any suitable semiconducting materials, insulating materials or conductive materials as needed. The substrate 302 may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire. The gate region 304 may be formed of silicon-containing dielectric material such as silicon oxide, or silicon nitride.

Each of the GAA FET modules, 301A, 301B illustrated in FIG. 3, include channel regions 312, which in some embodiments can be formed of nanosheets. The channel regions 312 extend through the gate region 304 to source/drain regions 305 on opposing sides of the gate region 304 in the X-direction. The source/drain regions 305 may be wider in the Y-direction than the channel region 312. The source/drain regions 305 may be separated from other source/drain regions 305 by the gate region 304 in the X-direction, and isolated by dielectrics in the Y-direction, and/or Z-direction.

In some embodiments, the source/drain (SD) regions 305 illustrated in FIG. 3 are coupled to the channel regions 312 by respective contact structures 308. The contact structures 308 (e.g., channel extension regions) are formed between the gate region 304 and the SD regions 305. The contact structures 308 are disposed through spacers (not shown). The GAA FET modules, 301A and 301B, each include respective SD regions 305. The contact structures 308, may include a silicon-based material, or a material containing silicon, such as a silicon/germanium (SiGe). One or more contact structures 308 may include a silicon-containing material with dopants. The dopants include may be an n-type or p-type dopant.

In some embodiments, the SD regions 305 are disposed vertically above an isolation layer 303. The isolation layer 303 is disposed between the substrate 302 and the gate region 304. A first extension 302A and a second extension 302B extend from the substrate 302 and through the isolation layer 303. The isolation layer 303 is generally in contract with the SD regions 305 and the gate region 304. In some embodiments, the first extension 302A and the second extension 302B are the same material as the substrate 302. The gate region 304 includes an axis 322. The axis 322 is perpendicular to the channel regions 312.

The channel regions 312 include channel interface regions 310 extending along the X-direction within the gate region 304. The channel interface region 310 includes a dielectric material that is disposed between channel region 312 and gate region 304.

In some embodiments, the dielectric material of the channel interface regions 310 include (e.g., hafnium dioxide (HfO₂), zirconium dioxide (ZrO₂), and/or titanium dioxide (TiO₂)) with a dielectric constant (K) higher than silicon dioxide (SiO₂) (e.g., K=3.9). In some embodiments, the dielectric material may be referred to as a high-K dielectric. In some embodiments, the gate metal layer may itself be formed of multiple metal layers each comprised of an electrically conductive material. The electrically conductive material may include various metal alloys, metals, or conductive ceramics including but is not limited to, one or more of Aluminum (AI), chromium (Cr), cobalt (Co), copper (Cu), gold (Au), hafnium (Hf), iridium (Ir), iron (Fe), lanthanum (La), manganese (Mn), molybdenum (Mo), niobium (Nb), platinum (Pt), rhodium (Rh), ruthenium (Ru), silver (Si), tantalum (Ta), tin (Sn), titanium (Ti), tungsten (W), vanadium (V), yttrium (Y), zirconium (Zr), and combinations thereof.

### Processing Sequence Example

FIGS. 2A illustrates a process flow diagram of a method 200a of forming a semiconductor device 400 according to one or more embodiments.

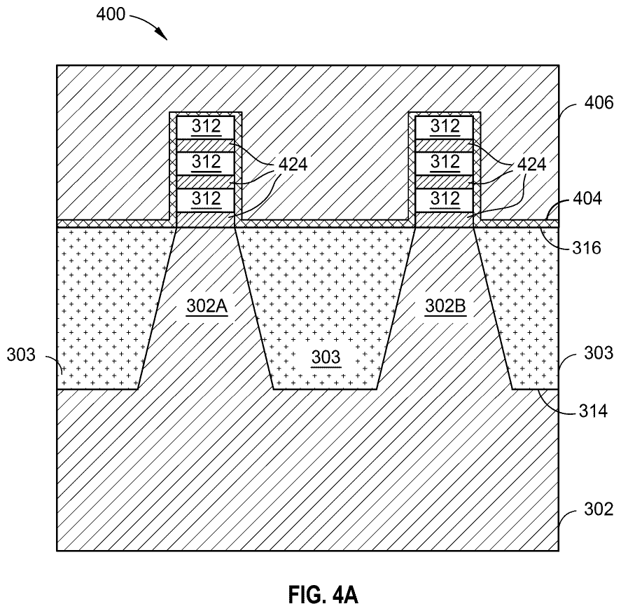

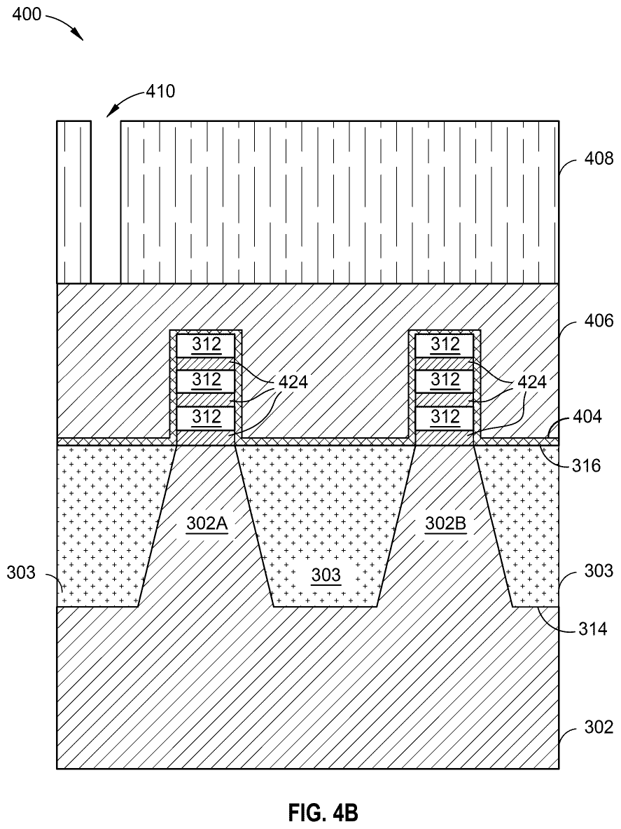

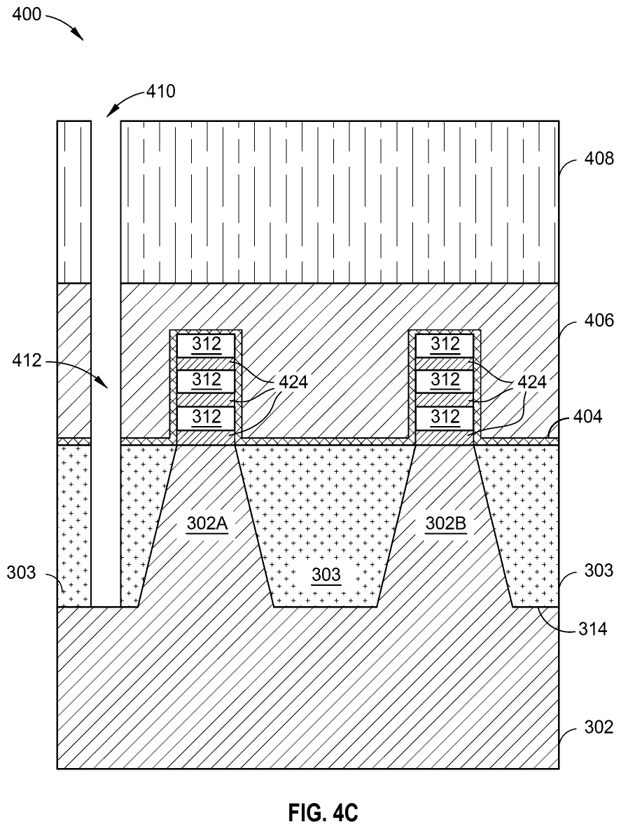

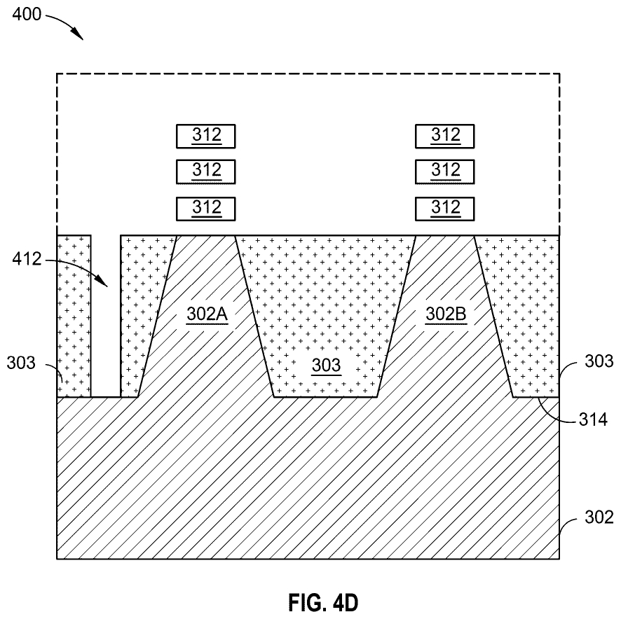

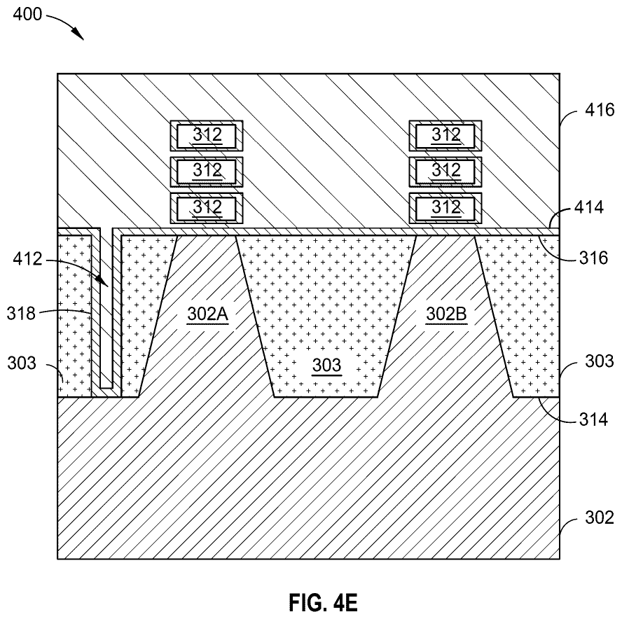

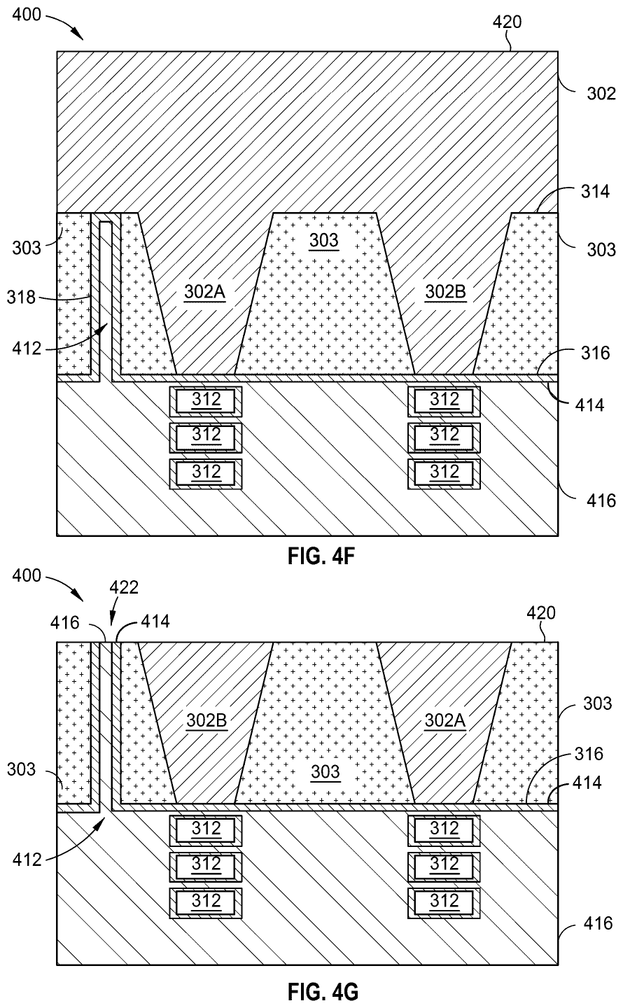

The method 200a of forming a semiconductor device is described with reference to FIGS. 4A-4G. FIGS. 4A-4G illustrate cross-sectional views of portions of the semiconductor device 400 formed during the operations of method 200a as illustrated FIG. 2A.

While method 200a is described using an example of a portion of a GAA FET, method 200a is not limited to a specific transistor type or construction. Further, FIGS. 4A-4G only illustrate a portion of a semiconductor device 400 when viewed by use of a plane that includes a cross section line A-A and axis 322 illustrated in FIG. 3.

FIG. 4A illustrates a two-dimensional cross-sectional view of a portion of a GAA FET device 400. At operation 210 of the method 200a, the device 400 is transferred to a processing chamber in a processing system. For example, the device 400 is transferred to the processing chamber 132 within the processing system 100. The device 400 includes the substrate 302, the isolation layer 303, the first extension 302A, the second extension 302B, an oxide layer 404, and a polysilicon layer 406 disposed on the oxide layer 404. The isolation layer 303 is disposed on a first surface 314 of the substrate 302. The oxide layer 404 is disposed on a first isolation surface 316 of the isolation layer 303. The first extension 302A and the second extension 302B extend from the first surface 314 of the substrate 302, through the isolation layer 303 and to the same plane as the first isolation surface 316 of the isolation layer 303.

The Isolation layer 303 is formed of a dielectric material. For example, the Isolation layer 303 may include silicon dioxide, silicon nitride, silicon oxynitride, high-k materials, polysilicon, spin-on glass, boron phosphosilicate glass, or combinations thereof.

The oxide layer 404 disposed on and over the isolation layer 303, and the plurality of channels formed over the first extension 302A and the second extension 302B. The oxide layer 404 may be formed of any suitable dielectric material. For example, the oxide layer 404 may include, but is not limited to: silicon dioxide, silicon nitride, silicon oxynitride, high-k materials, polysilicon, spin-on glass, boron phosphosilicate glass, or combinations thereof. The device 400 includes a polysilicon layer 406 disposed on the oxide layer 404.

Prior to the operation 220 of method 200a, surface contamination may be present on the device features. These surface contaminates, such as native oxides, may be formed on one or more of the surfaces of the device features, such as a silicon dioxide formed on exposed surfaces. The surface contaminants may also be of varying thickness depending on the circumstances of formation, such as exposure to the atmosphere or oxygen while the device 400 was at an elevated temperature.

Operation 220 of method 200a is an optional operation that incudes subjecting the device 400 to a cleaning process that is used to clean the exposed surfaces of the substrate, such as the surface of the polysilicon layer 406. The operation 220 may be performed in a process chamber, for example, the processing chamber 110 or 114 within the processing system 100. In one example, the cleaning process converts exposed silicon oxide containing material into a silicon containing material. In another example, operation 220 includes a cleaning etch process, such as an exposing the device 400 to an ammonium fluoride dry etching process. Ammonium fluoride as described herein includes one or more of ammonium fluoride (NH4F) and ammonium hydrogen fluoride (NH₄F·HF).

In one example, the cleaning process preformed in operation 220 includes introducing both a hydrogen-containing precursor and a fluorine-containing precursor into a plasma/carrier gas. For example, ammonia (NH₃) may be the hydrogen-containing precursor and nitrogen trifluoride (NF₃) may be the fluorine-containing precursor introduced into the plasma/carrier gas mixture.

In another example, the cleaning process of operation 220 includes maintaining an etching rate of the ammonium fluoride etchingocess based upon the ratio of hydrogen-containing precursor to fluorine-containing precursor. A greater amount of fluorine-containing precursor to hydrogen-containing precursor will produce an ammonium fluoride etchant with relatively greater reactivity. In one or more embodiments, the molar ratio of hydrogen-containing precursor to fluorine-containing precursor introduced is in a range of from about 1:3 to 3:1, such as from about 1:3, 1:2.5, 1:2, 1:1.5 or 1:1 to about 1.5:1, 2:1, 2.5:1, or 3:1, including the endpoint values and all values in between.

In one or more embodiments, operation 220 further comprises maintaining the device 400 at a first deposition temperature. The first deposition temperature permits the ammonium fluoride etchant to condense out of the plasma/carrier gas and deposit as a solid onto the device 400. In one or more embodiments, the first deposition temperature may be at a value that prevents substantial reaction of the deposited ammonium fluoride etchant with the native oxides present during deposition. The device 400 temperature may then be raised after deposition to facilitate regulation of the rate of reaction of the deposited ammonium fluoride etchant. In one or more embodiments, the first deposition temperature may be at a value where the ammonium fluoride etchant is deposited on the device 400 surfaces and immediately or near-immediately reacts with the silicon oxides present on the surfaces. In one or more embodiments, the device 400 may be maintained at a first deposition temperature of less than 120° C., such as in a range of from about −30° C. to 120° C., such as from about −30° C., −20° C., −10° C., 0° C., 10° C., 20° C., 30° C., 40° C., 50° C., and 60° C. to 70° C., 75° C., 80° C., 85° C., 90° C., 95° C., 100° C., 105° C., 110° C., 115° C., and 120° C., and such as in a range of from about 0° C. to 75° C., including the endpoint values and all values in between.

In another example, the cleaning process performed in operation 220 of method 200a includes generating a plasma formed with a carrier gas. The plasma/carrier gas combination may then be introduced to the surface of the device 400 with or without bias. In one or more embodiments, the carrier gas may comprise, consist, or consist essentially of a noble gas, such as argon, neon, and helium, and combinations thereof. In some examples, the hydrogen containing gas, such as H2, and a carrier gas, such as argon (Ar), are provided to the surface of the device 400 while a bias is applied to the substrate 320.

The cleaning process in operation 220 may also include a rinse, or series of rinses using deionized water, an organic solvent bath of acids and hydrogen peroxide. For example, cleaning process performed in operation 220 of method 200a may include a sequence of baths including a first bath in a mixture containing deionized water, hydrogen peroxide, and ammonium hydroxide, followed by rinsing in deionized water, and then a second bath in a mixture containing deionized water and hydrochloric acid. In some embodiments, operation 220 of method 200a includes an ultrasonic cleaning operation. For example, the cleaning process performed in operation 220 of method 200a may include spin drying, or drying by purging with nitrogen gas. Each channel region 312 is separated by alternating layers regions 424. The alternating layers regions 424 are alternating layers of silicon and silicon-germanium. The alternating layers regions 424 are disposed between each channel region 312 and between the channel region 312 and the respective first extension 302A and second extension 302B. The channel region 312 and alternating layers regions 424 are covered with a conformal oxide film. The conformal oxide film is oxide layer 404 according to some embodiments.

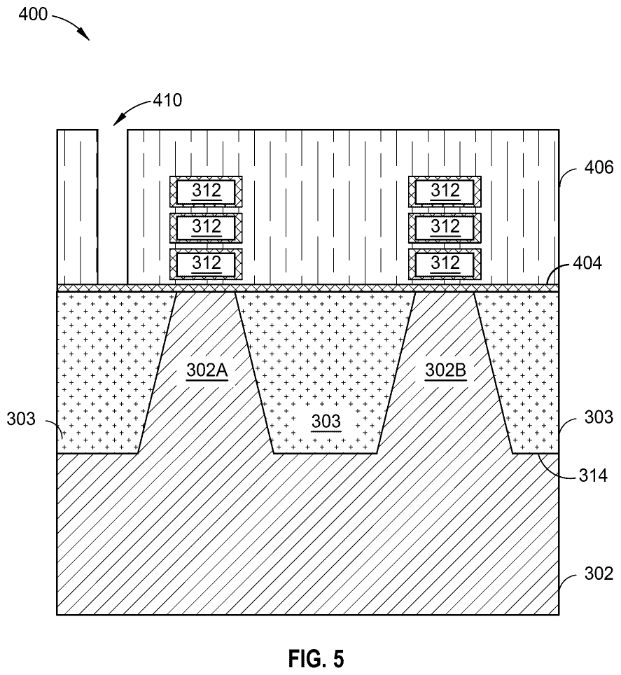

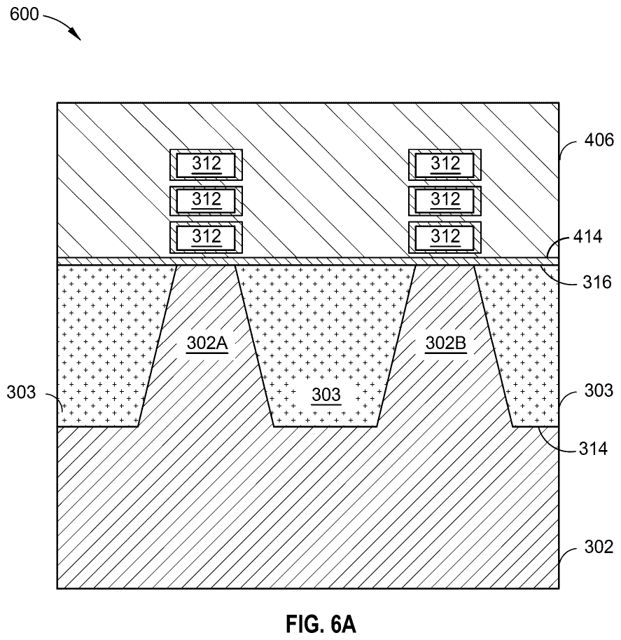

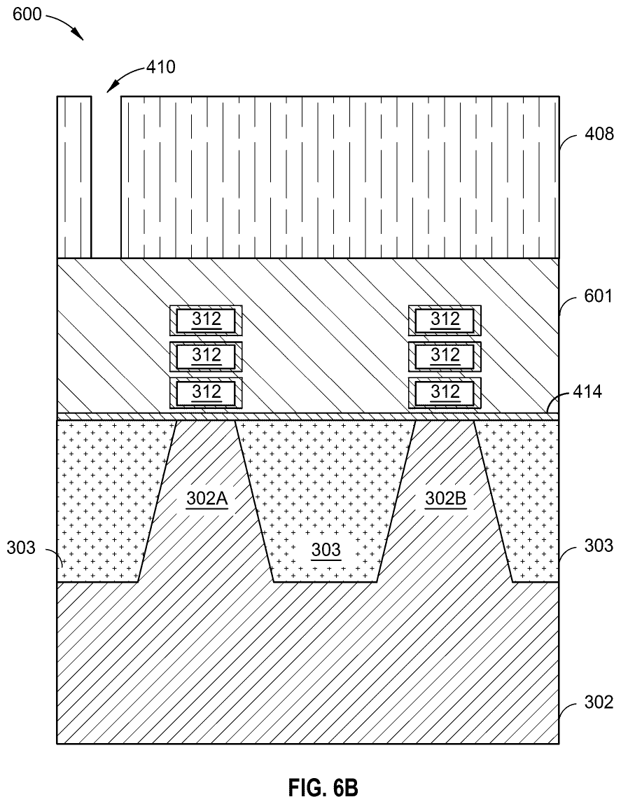

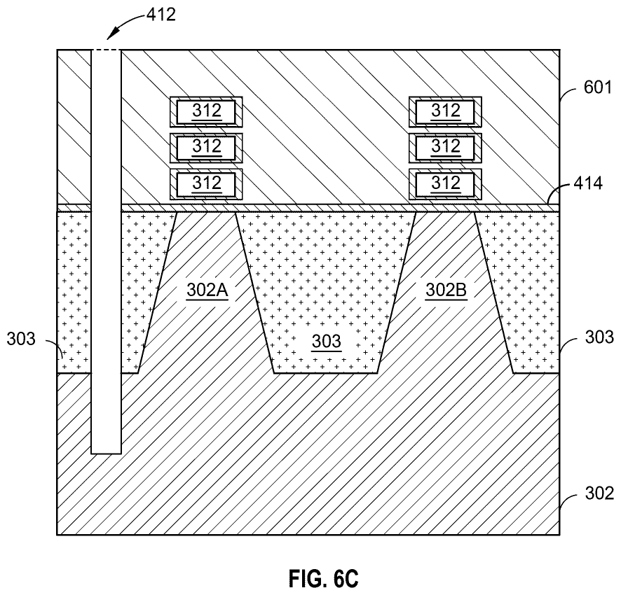

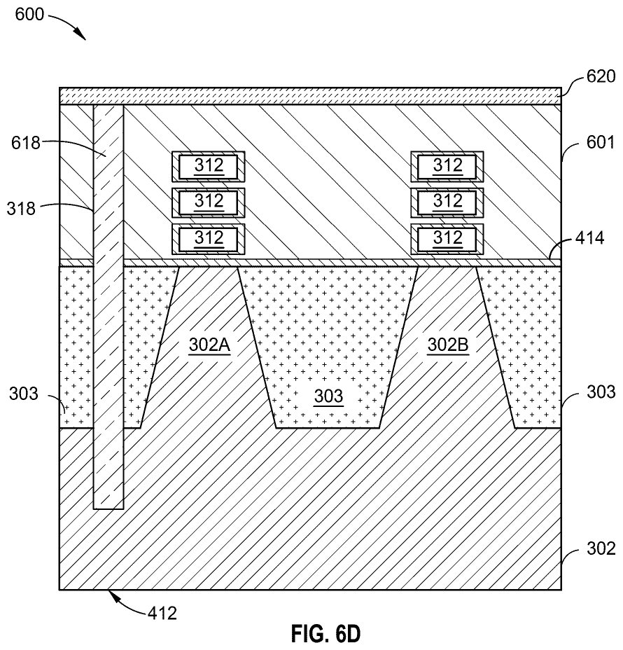

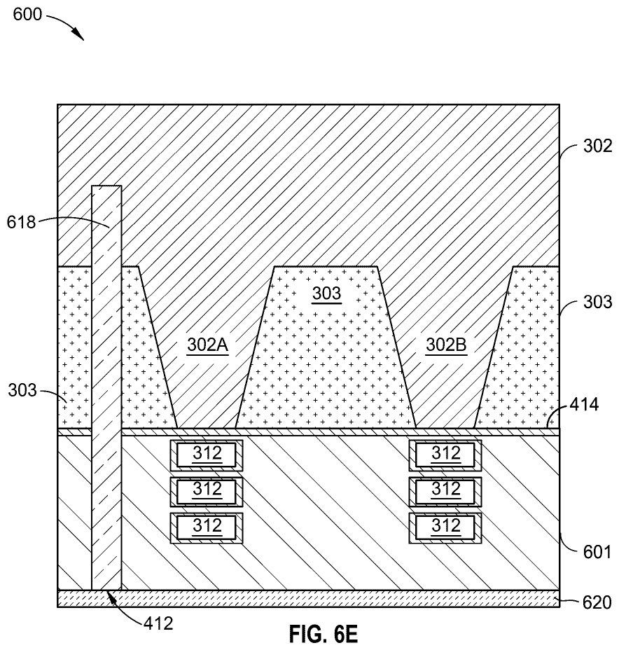

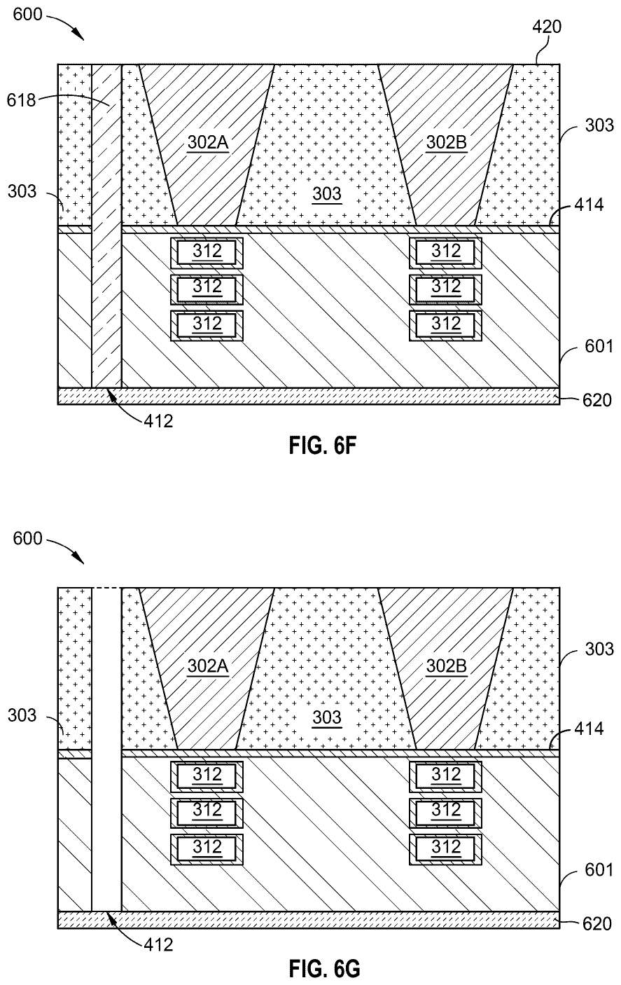

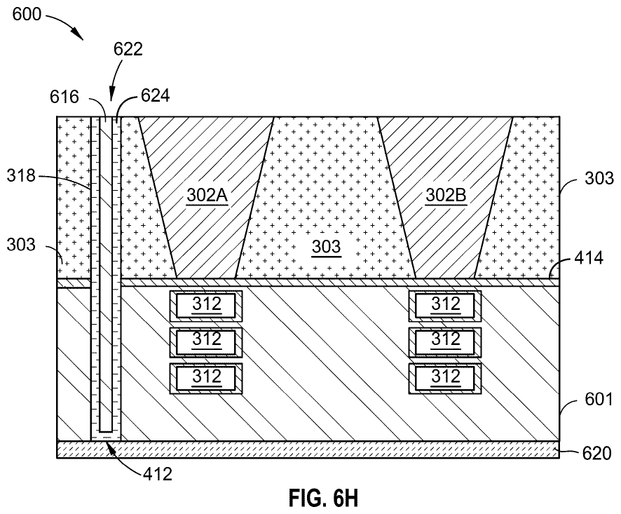

Operation 230 of method 200a, as illustrated in FIG. 4B, includes forming a patterned resist layer 408 on the polysilicon layer 406. Depositing the resist layer 408 may be performed by any suitable resist deposition process. Patterning the resist layer 408 may be performed by any suitable lithography process. For example, the resist layer 408 may be patterned using an optical lithography process, an extreme ultraviolet (EUV) lithography process, x-ray lithography process, an electron beam lithography process, a nanoimprint lithography process, a step and flash imprint lithography process, maskless lithography process, or similar process. The resist layer 408 includes a pattern with a pattern 410 through the resist layer 408. The pattern 410 extends from the top of the resist layer 408 to polysilicon layer 406. While not shown in FIGS. 4B-4G, and also in FIGS. 5-6H, in some configurations the pattern 410 and subsequently formed high-aspect-ratio feature 412 can be aligned, positioned and formed between adjacent nanosheet stacks (e.g., positioned between the first extension 302A and second extension 302B) so that a backside gate contact can make self-aligned contact with gate metal layer(s).

Operation 240 of method 200a, as shown in FIG. 4C, includes performing an etching process on the device 400. The etching process may be a reactive ion etching (RIE) process but other etching process are contemplated. During the etching process, the processing chamber operates at a vacuum pressure. As shown in FIG. 4C the etching process forms a high-aspect ratio (HAR) feature 412 through the resist layer 408, the polysilicon layer 406, the oxide layer 404, and the isolation layer 303, to the first surface 314 of the substrate 302. The forming of the HAR feature 412 includes removing a portion of the isolation layer 303 and the polysilicon layer 406. The HAR feature 412 is formed a first distance in a second direction from the plurality of channels 312. For example, the HAR feature 412 is formed a first distance along the axis 322 (FIG. 3) of the gate region 304 (FIG. 3) from the plurality of channels 312. In some embodiments, the HAR feature 412 is formed based on the layout of other metallic write line locations.

In some embodiments, the HAR feature 412 is formed between the plurality channels 312 formed over the first extension 302A and the plurality channels 312 formed over the second extension 302B. In some embodiments, the first distance includes the HAR feature 412 being formed within 50 nanometers or less from the plurality channels 312. In some embodiments, the etching process removes the polysilicon layer 406, the oxide layer 404, and the alternating layer regions 424.

In some embodiments, operation 240 includes a different dry etching process, or combination of processes to form the HAR feature 412. Operation 240 does not etch the channels 312, the first extension 302A, or the second extension 302B. The HAR feature 412 is formed away from the channels 312, the first extension 302A, or the second extension 302B. In some embodiments, operation 240 includes a first etch that etches the polysilicon layer 406 and the oxide layer 404 and a second etch to etch the isolation layer 303. The first etch is a different etch than the second etch. The etching of the polysilicon layer 406 and the oxide layer 404 and the isolation layer 303 may be a selective etch process that includes a first etch operation that etches the polysilicon layer 406 and a second etch operation that etches the oxide layer 404 and the isolation layer 303. The first etch includes a first etch fluid that includes one or more of bromine, fluorine, and chlorine. The second etch includes a second etch fluid that includes fluorine without chlorine or bromine. In some embodiments, the etching of the polysilicon layer 406 and the oxide layer 404 and the isolation layer 303 is a non selective etch where all three are etched in a single chamber in a single operation.

FIG. 4D illustrates the device 400 after operation 250 of method 200a. Operation 250 includes removal of the resist layer 408, the polysilicon layer 406, and the oxide layer 404. Removal of the resist layer 408 may be accomplished through a dry stripping process or a wet stripping process, and is generally in one portion of operation 250 is selective to the removal of the polysilicon layer 406 relative to the adjacent dielectric layers, and in a second part that is selective to the removal of the oxide layer 404 to other exposed dielectric and silicon containing materials.

Removal of the polysilicon layer 406 may be accomplished through an etching process, for example, a dry etching process or a wet etching process. The etching process may include reactive ion etching (RIE), inductively coupled plasma (ICP) etching, capacitively coupled plasma (CCP) etching, or other suitable dry etching process. In one example, the etching of the polysilicon layer 406 can be accomplished by use of plasma etching process that includes the use of etch gases that can include at least one of F-containing gas (e.g., NF₃, F₂, or HF), a H-containing gas (e.g., H₂, NH₃, or an amine).

A wet etching process may include immersing the device 400 in a chemical solution that selectively reacts with and etches the polysilicon layer 406.

FIG. 4E illustrates the device 400 after operation 260 of method 200a. Operation 260 includes depositing a dielectric layer 414 and a gate metal fill layer 416 on the device 400. The dielectric layer 414 is deposited on the exposed surfaces of the channel regions 312, the first isolation surface 316 of the isolation layer 303, the first extension 302A, the second extension 302B, the first surface 314, and on sidewalls 318 of the HAR feature 412. The sidewalls 318 are the surfaces of the isolation layer 303 exposed during the etching process in operation 240. The gate metal fill layer 416 is deposited on the dielectric layer 414 and into the HAR feature 412. The deposition of the gate metal fill layer 416 extends to the first surface 314 such that the gate metal fill layer 416 is deposited on the first surface 314 of the substrate 302. The dielectric layer 414 separates the gate metal fill layer 416 from the channel regions 312, the first isolation surface 316 of the isolation layer 303, the first extension 302A, the second extension 302B, and on sidewalls 318 of the HAR feature 412. The distance between the sidewalls 318 of the HAR feature 412 can be 25 nanometers or less. For example, if the HAR feature 412 is a cylindrical hole, the HAR feature 412 may have a diameter of 25 nanometers or less.

While shown as a monolithic structure, the dielectric layer 414 may include multiple layers and structures. For example, the dielectric layer 414 may include one or more interlayer dielectric (ILD) material layers, one or more high-k dielectric material layers, one or more metal barrier layers, one or more gate metal layers, or any combination thereof.

The dielectric material layers may include, but is not limited to, silicon dioxide (SiO₂), silicon nitride (Si₂N₄), organosilicate glass (OSG), fluorinated silicate glass (FSG), Black Diamond®, organic dielectrics, low-k dielectrics, or combinations thereof. The one or more dielectric layers may be formed by any suitable deposition process, including, but not limited to, plasma oxidation, physical vapor deposition (PVD), chemical vapor deposition (CVD), atomic layer deposition (ALD), or any combination thereof. The deposition of the gate metal fill layer 416 may include intermediary steps such as cleaning, chemical-mechanical polishing (CMP), or other processes common to semiconductor device manufacturing.

The one or more high-k dielectric layers of the dielectric layer 414 may include a high-k dielectric material. The high-k dielectric material may include, but is not limited to, silicon dioxide (SiO₂), hafnium dioxide (HfO₂), zirconium dioxide (ZrO₂), lanthanum oxide (La₂O₃), aluminum oxide (Al₂O₃), yttrium oxide (Y₂O₃), titanium dioxide (TiO₂), Barium Strontium Titanate (BaSrTiO₃), rare earth metal oxides, materials with a dielectric constant (k) greater than about 3.9, or any combination thereof. The one or more high-k dielectric layers may be formed by any suitable deposition process, including, but not limited to, physical vapor deposition (PVD), chemical vapor deposition (CVD), atomic layer deposition (ALD), or any combination thereof. The deposition process may include intermediary steps such as cleaning, chemical-mechanical polishing (CMP), or other processes common to semiconductor device manufacturing.

The one or more metal layers of the dielectric layer 414 may include an electrically conductive material. The electrically conductive material may include, but is not limited to, one or more of Aluminum (AI), chromium (Cr), cobalt (Co), copper (Cu), gold (Au), hafnium (Hf), iridium (Ir), iron (Fe), lanthanum (La), manganese (Mn), molybdenum (Mo), niobium (Nb), platinum (Pt), rhodium (Rh), ruthenium (Ru), silver (Si), tantalum (Ta), tin (Sn), titanium (Ti), tungsten (W), vanadium (V), yttrium (Y), zirconium (Zr), metal alloys, metal oxides, metal nitrides, metal silicides, other metals, conductive ceramics, or any combination thereof. The one or more metal layers may be disposed may be formed by any suitable deposition process, including, but not limited to, physical vapor deposition (PVD), chemical vapor deposition (CVD), atomic layer deposition (ALD), or any combination thereof. The deposition process may include intermediary steps such as cleaning, chemical-mechanical polishing (CMP), or other processes common to semiconductor device manufacturing.

While shown as a monolithic structure in FIG. 4E, in practice, the gate metal fill layer 416 may include one or more one or more metal layers (e.g., n-metal or p-metal layers) with electrically conductive material. The electrically conductive material may include, but is not limited to, one or more of Aluminum (Al), chromium (Cr), cobalt (Co), copper (Cu), gold (Au), hafnium (Hf), iridium (Ir), iron (Fe), lanthanum (La), manganese (Mn), molybdenum (Mo), niobium (Nb), platinum (Pt), rhodium (Rh), ruthenium (Ru), silver (Si), tantalum (Ta), tin (Sn), titanium (Ti), tungsten (W), vanadium (V), yttrium (Y), zirconium (Zr), metal alloys, metal oxides, metal nitrides, metal silicides, other metals, conductive ceramics, or any combination thereof. The gate metal fill layer 416 may be formed by any suitable deposition process, including, but not limited to, physical vapor deposition (PVD), chemical vapor deposition (CVD), atomic layer deposition (ALD), or any combination thereof. The gate metal fill layer 416 deposition process may include intermediary steps such as cleaning, chemical-mechanical polishing (CMP), or other processes common to semiconductor device manufacturing.

FIG. 4F illustrates the device 400 after operations 270 and 280 of method 200a. At operation 270, the device 400 is inverted (e.g., turned over or flipped). When flipped, the substrate 302 is disposed over the isolation layer 303, dielectric layer 414, and the gate metal fill layer 416.

During operation 280, a portion of the substrate 302 is removed to expose a lower surface 420 of the isolation layer 303. Removal of the portion of the substrate 302 may be accomplished through a dry etching process, a wet etching process, a CMP process or combination thereof. The lower surface 420 is disposed opposite the first isolation surface 316 of the isolation layer 303. The removal of the substrate 302 also exposes a contact region 422 and a surface of the first extension 302A and the second extension 302B. The contact region 422 is region in which a backside gate contact is formed. The contact region 422 is aligned with the axis 322 of the gate region 304 (FIG. 3).

The contact region 422 formed by method 200a enables a self-aligned gate contact through the backside of the device. By self aligning the contact region 422 of the device 400, a bottom device gate with backside signal lines, a cross-couple local interconnect, other local wiring constructs, or any combination thereof is enabled.

Traditional devices rely on front side contacts with the gate region 304 (FIG. 3). The method 200a enables the formation of the device 400 that can be placed on other devices with a gate contact already formed. In contrast, if a contact is not formed, additional processes are required, reducing throughput. Further, the device 400 would further reduce front side device wiring congestion and reduce parasitic gate capacitance by moving a local front side gate contact local to the less congested back side.

Operation 290 is an optional operation that includes additional processing of the device 400 to form a metal interconnect structure that is coupled to the contact region 422. Additional processing may include the deposition of one or more passivation layers, one or more dielectric layers, forming front or back side metal layers within the one or more dielectric layers, front or back side local wiring, front or back side interconnects, etching front or back side vias, coupling the device 400 to other devices or structures, or any combination thereof.

### Alternate Processing Sequence Example

FIG. 5 illustrates a cross-sectional view of a portion of the semiconductor device 400 undergoing operations described in method 200b. A process flow diagram of the method 200b is illustrated in FIG. 2B.

While method 200b is described using an example of a portion of a GAA FET, method 200b is not limited to a specific transistor type or construction. Further, FIG. 5 only illustrates a portion of a semiconductor device substrate. In practice, additional layers and structures may be disposed above, below, or within those depicted in FIG. 5.

As shown in FIG. 2B, method 200b provides alternate processing operations. The method 200b includes a different order of operations.

Method 200b includes operation 230 where the polysilicon layer 406 is removed. As illustrated in FIG. 5, after the device 400 has been disposed in a processing chamber, the polysilicon layer 406 is removed to expose the oxide layer 404.

Method 200b includes operation 230A where a resist layer 408 is applied after the polysilicon layer 406 is removed. The resist layer 408 is disposed on the exposed oxide layer 404 after the polysilicon layer 406 has been etched away. As illustrated in FIG. 5, after the device 400 has been disposed in a processing chamber, the polysilicon layer 406 has been removed to expose the oxide layer 404. The patterned resist layer 408 is formed on the exposed oxide layer 404 of the device 400. The remainder of method 200b mirrors method 200a in which operations 240-290 are then completed. The process recipes for each of these operations in method 200b will generally remain the same as the operations in method 200a.

### Second Alternate Processing Sequence Example

FIGS. 6A-6G illustrate cross-sectional views of portions of a semiconductor device during operations of a method 200c of FIG. 2C.

While method 200c is described using an example of a portion of a GAA FET, method 200c is not limited to a specific transistor type or construction. Further, FIGS. 6A-6G only illustrate a portion of a semiconductor device substrate. In practice, additional layers and structures may be disposed above, below, or within those depicted in FIGS. 6A-6G. The method 200c in FIG. 2C illustrates a method of forming a device 600 with a backside contact.

FIG. 6A illustrates a device 600 at operation 210 of method 200c, which includes a device 600 in which a gate metal layer 601 has been formed within the gate region 304. The device 600 includes the substrate 302, the first extension 302A, the second extension 302B, the isolation layer 303, the dielectric layer 414, and a gate metal layer 601. The gate metal layer 601 is disposed on the device 600. The gate metal layer 601 is separated from the channel regions 312 and the first isolation surface 316 by the dielectric layer 414.

The dielectric layer 414 is disposed onto the plurality of channels 312, the upper surface of the first extension 302A, the second extension 302B.

In operation 210, the device 400 is transferred to a processing chamber within a processing system.

Operation 220 of method 200c includes optionally subjecting the device 600 to a cleaning process. The optional cleaning process is similar to the operation 220 of method 200a.

FIG. 6B illustrates the device 600 after operation 230 of method 200c. Operation 230 includes depositing the patterned resist layer 408 above the gate metal fill layer 416. The resist layer 408 is a patterned resist. In some embodiments, the resist layer 408 is a patterned photoresist. The resist layer 408 is deposited on a gate metal layer 601.

FIG. 6C illustrates the device 600 after operation 240 of method 200c. At operation 240, as shown in FIG. 6C, the resist layer 408 (FIG. 6B) has been removed and the gate metal layer 601 of the device 600 is etched to partially form the HAR feature 412. The resist layer 408 is removed by an ashing, a dry etch, a wet etch, a thermal process, or other photoresist removal methods. Removal of the resist layer 408 is described above in method 200a.

As shown in FIG. 6C the gate metal layer etching process partially forms a high-aspect ratio (HAR) feature 412 through the gate metal layer 601. In some embodiments, operation 240 includes multiple different dry etching processes to form the HAR feature 412 within the gate metal layer 601. Operation 240 does not significantly etch the channels 312, the first extension 302A, or the second extension 302B.

FIG. 6C illustrates the device 600 after operation 240A of method 200c. At operation 240A, as further shown in FIG. 6C, the isolation layer 303, and portion of the substrate 302 of the device 600 are etched to form the HAR feature 412. The etching process of operation 240A of method 200c may be similar to the etching process of operation 240 of method 200a with addition of an etching process that includes etching the HAR feature 412 through a portion of the substrate 302. As shown in FIG. 6C, the etching process forms the high-aspect ratio (HAR) feature 412, through the gate metal layer 601, the dielectric layer 414, and the isolation layer 303, and portion of the substrate 302. In some embodiments, operation 240A includes multiple different dry etching processes to form the HAR feature 412. Operation 240A does not significantly etch the channels 312, the first extension 302A, or the second extension 302B.

FIG. 6D illustrates the device 600 after operation 250 of method 200c. In operation 250 of method 200c, the HAR feature 412 is filled with a dielectric filler material 618. The dielectric filler material 618 may include one or more of silicon dioxide, silicon nitride, silicon oxynitride, low-k materials, high-k materials, polysilicon, spin-on glass, boron phosphosilicate glass, or combinations thereof. The dielectric filler material 618 may be formed by any suitable deposition process, including, but not limited to, physical vapor deposition (PVD), chemical vapor deposition (CVD), atomic layer deposition (ALD), or any combination thereof. The deposition process may include intermediary steps such as cleaning, chemical-mechanical polishing (CMP), or other processes common to semiconductor device manufacturing. The dielectric filler material 618 extends through the gate metal layer 601 to the substrate 302.

The dielectric filler material 618 protects the sidewalls 318 of the HAR feature 412 during subsequent processing by preventing deposition within the HAR feature 412 or etching of the sidewalls 318.

In some embodiments, the operation 250 of method 200c includes depositing a nitride cap layer 620 over the dielectric filler material 618 and the gate metal layer 601. The nitride cap layer 620 operates to protect the gate metal layer 601 during subsequent processes. In some embodiments, the nitride cap layer 620 is able to function as a sacrificial layer for subsequent depositions.

FIG. 6E illustrates the device 600 after operation 260 of method 200c. As illustrated in FIG. 6E, the device 600 is inverted (e.g., turned over).

FIG. 6F illustrates the device 600 after operation 270 of method 200c. During operation 270 of method 200c, an etching process is performed and a portion of the substrate 302 is removed. In this embodiment, the removed portion of the substrate 302 extends to the top (formerly the bottom) of the first extension 302A, and the second extension 302B. For example, the substrate 302 is etched away to expose lower surface 420 and the dielectric filler material 618 within the HAR feature 412. In some embodiments, the dielectric filler material 618 is co-planar with the lower surface 420.

The etching process that removes the substrate 302 may be a dry etching process or a wet etching process. In some embodiments the substrate 302 is removed by a CMP process.

FIG. 6G illustrates the device 600 after operation 280 of method 200c. During operation 280, the dielectric filler material 618 is removed from the HAR feature 412. Removal of the dielectric filler material 618 may performed by a dry etching process or a wet etching process. In one example, the dry etching process can include supplying a fluorinated etching gas, such as an HF containing gas during the etch process. In one example, the fluorinated etching gas includes a nitrogen free hydrogen containing gas. The fluorinated etching gas may include H₂, H₂O, H₂O₂, and the like. An inert gas may also be supplied into the etching gas mixture, as needed, to assist the profile control. Examples of the inert gas supplied in the gas mixture include Ar, He, Ne, Kr, Xe and the like. In one particular example, the etching gas mixture includes HF and H₂. During operation 280, the dielectric filler material 618 is removed to exposes the nitride cap layer 620 through the HAR feature 412.

FIG. 6H illustrates the device 600 after operation 290 of method 200c. During operation 290, a metal liner 624 and a gate metal fill 616 are disposed within the HAR feature 412. The deposition of the metal liner 624 occurs before the deposition of the gate metal fill 616. The metal liner 624 is disposed on the sidewalls 318 and the nitride cap layer 620. Once the metal liner 624 has been formed, the gate metal fill 616 is selectively deposited within the HAR feature 412 and on the metal liner 624. The deposited metal liner 624 and the gate metal fill 616 form a contact region 622. The contact region 622 is co-planar with the lower surface 420. The contact region 622 enables the device 600 to function with a back side gate contact that is aligned with the axis 322 of the gate region 304 (FIG. 3). The metal liner 624 is a conductive material and may include one or more of a metal, tantalum, titanium, hafnium, aluminum, a nitride, an oxide, or any combination thereof. For example, the metal liner 624 includes titanium nitride or tantalum nitride.

The contact region 622 formed by method 200c enables a self-aligned gate contact through the backside of the device 600. By self aligning the contact region 622 of the device 600, a bottom device gate with backside signal lines, a cross-couple local interconnect, other local wiring constructs, or any combination thereof is enabled.

Traditional devices rely on front side contacts with the gate region 304 (FIG. 3). The method 200c enables the formation of the device 600 that can be placed on other devices with a gate contact already formed. In contrast, if a contact is not formed, additional processes are required, reducing through put. Further, the device 600 would further reduce front side device wiring congestion and reduce parasitic gate capacitance by moving a local front side gate contact local to the less congested back side.

Following operation 290, optional operation 299 may be performed on the device 600 that includes additional processing of the device 400 to form a metal interconnect structure that is coupled to the contact region 422. Additional processing may include the deposition of one or more passivation layers, one or more dielectric layers, forming front or back side metal layers within the one or more dielectric layers, front or back side local wiring, front or back side interconnects, etching front or back side vias, coupling the device 400 to other devices or structures, or any combination thereof.

### Additional Considerations

While this specification contains many specific implementation details, these should not be construed as limitations on the scope of what may be claimed, but rather as descriptions of features that may be specific to particular implementations. Certain features that are described in this specification in the context of separate implementations may also be implemented, in combination, in a single implementation. Conversely, various features that are described in the context of a single implementation may also be implemented in multiple implementations, separately, or in any suitable sub-combination.

Moreover, although previously described features may be described as acting in certain combinations and even initially claimed as such, one or more features from a claimed combination may, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations. It should be understood that the described program components and systems may generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

While the various steps in an embodiment method or process are presented and described sequentially, one of ordinary skill in the art will appreciate that some or all of the steps may be executed in different order, may be combined or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram.

Unless defined otherwise, all technical and scientific terms used have the same meaning as commonly understood by one of ordinary skill in the art to which these systems, apparatuses, methods, processes and compositions belong.

In this disclosure, the terms “top”, “bottom”, “side”, “above”, “below”, “up” “down”, “upward”, “downward”, “horizontal”, “vertical”, and the like do not refer to absolute directions. Instead, these terms refer to directions relative to a nonspecific plane of reference. This non-specific plane of reference may be vertical, horizontal, or other angular orientation.

The singular forms “a,” “an,” and “the” include plural referents, unless the context clearly dictates otherwise. Within a claim, reference to an element in the singular is not intended to mean “one and only one” unless specifically so stated, but rather “one or more.” Unless specifically stated otherwise, the term “some” refers to one or more.

Embodiments of the present disclosure may suitably “comprise”, “consist” or “consist essentially of” the limiting features disclosed, and may be practiced in the absence of a limiting feature not disclosed. As used here and in the appended claims, the words “comprise,” “has,” and “include” and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

As used, the term “determining” encompasses a wide variety of actions. For example, “determining” may include calculating, computing, processing, deriving, investigating, looking up, for example, looking up in a table, a database or another data structure, and ascertaining. Also, “determining” may include receiving, for example, receiving information, and accessing, for example, accessing data in a memory. Also, “determining” may include resolving, selecting, choosing, and establishing.

When the word “approximately” or “about” are used, this term may mean that there may be a variance in value of up to ±10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

As used herein, “a CPU,” “a processor,” “at least one processor” or “one or more processors” generally refers to a single processor configured to perform one or multiple operations or multiple processors configured to collectively perform one or more operations. In the case of multiple processors, performance the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims.

In the claims, means-plus-function clauses are intended to cover the structures described as performing the recited function and not only structural equivalents, but also equivalent structures. For example, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. § 112(f), for any limitations of any of the claims, except for those in which the claim expressly uses the words ‘means for’ together with an associated function.

The following claims are not intended to be limited to the embodiments provided but rather are to be accorded the full scope consistent with the language of the claims.

What is claimed is:

1. A method of forming a contact structure on a substrate, comprising:
forming a high aspect ratio (HAR) feature within a substrate, the substrate comprising a device formed on the substrate, wherein
the device comprises:
a plurality of channels disposed through a polysilicon layer and extending in a first direction; and
an isolation layer disposed on a surface of the substrate, the polysilicon layer separated from the isolation layer by a dielectric layer;
the forming of the HAR feature comprises removing a portion of the isolation layer and the polysilicon layer, the HAR feature formed a first distance in a second direction from the plurality of channels;
etching the polysilicon layer to expose a top surface of the isolation layer that is opposite to a surface that is disposed on the surface of the substrate; and
removing the substrate to expose a metal layer within the HAR feature.

2. The method of claim 1, further comprising:
before disposing the metal layer, depositing a dielectric layer over the isolation layer, on a sidewall of the HAR feature, and on the plurality of channels, wherein the dielectric layer is disposed between the plurality of channels and the metal layer.

3. The method of claim 1, wherein etching the polysilicon layer includes etching a dielectric layer by a dry etching process.

4. The method of claim 1, wherein etching the high aspect ratio (HAR) feature exposes a first surface of the substrate.

5. The method of claim 1, further comprising forming the metal layer within the HAR feature before removing the substrate.

6. The method of claim 1, wherein forming the HAR feature further comprises disposing a resist layer on the polysilicon layer.

7. The method of claim 1, wherein removing the substrate comprises a dry etching process and a chemical mechanical polishing (CMP) process.

8. A method of forming a contact structure on a substrate, comprising:
forming a high aspect ratio (HAR) feature within a substrate, wherein the substrate comprises a device formed in the substrate, the device comprising:
an isolation layer formed on the substrate; and
a plurality of channels surrounded by a polysilicon layer, the plurality of channels separated from the polysilicon layer by an oxide layer, and the polysilicon layer disposed over the isolation layer;
removing the polysilicon layer to expose the oxide layer;
patterning the exposed oxide layer and isolation layer to form a high aspect ratio (HAR) feature through the isolation layer, wherein the HAR feature extends to a first surface of the substrate;
depositing a metal layer within the HAR feature; and
removing the substrate to expose a contact region that comprises a portion of the metal layer.

9. The method of claim 8, wherein the contact region is co-planar with a surface of the isolation layer.

10. The method of claim 8, wherein removing the polysilicon layer comprises a dry etching process.

11. The method of claim 8, further comprising removing the oxide layer with a dry etching process.

12. The method of claim 8, further comprising depositing a dielectric layer on a sidewall of the HAR feature.

13. The method of claim 12, wherein the dielectric layer separates the metal layer from the sidewalls of the HAR feature.

14. The method of claim 12, wherein the dielectric layer includes an oxide.

15. The method of claim 8, wherein removing the substrate comprises one of a dry etching process or a chemical mechanical polishing (CMP) process.

16. A method of forming a contact structure on a substrate, comprising:
transferring a device into a processing chamber, wherein the device comprises:
a substrate comprising silicon;
an isolation layer formed on the substrate; and
a gate metal layer disposed above the an isolation layer;
etching the device to form a high aspect ratio (HAR) feature through the gate metal fill, the isolation layer, and the substrate;
depositing a dielectric filler material within the HAR feature;
removing the substrate to expose a lower surface of the isolation layer;
removing the dielectric filler material; and
disposing a gate metal fill within the HAR feature.

17. The method of claim 16, wherein the device further comprises:
disposing a metal liner on the isolation layer, the gate metal layer separated from the isolation layer by the metal liner.

18. The method of claim 17, further comprising depositing a dielectric filler material within the HAR feature before disposing the gate metal fill within the HAR feature.

19. The method of claim 17, wherein the metal liner is a conductive material.

20. The method of claim 16, wherein removing the substrate exposes the dielectric filler material coplanar with a lower surface of the isolation layer.
